(19) United States
(12) Patent Application Publication
(10) Pub. No.: US 2009/0168826 A1
(43) Pub. Date: Jul. 2, 2009

(54) Semiconductor lasers utilizing optimized n-side and p-side junctions

(75) Inventors: Jason Nathaniel Farmer, Vancouver, WA (US); Mark Andrew DeVito, Vancouver, WA (US); Zhe Huang, Vancouver, WA (US); Paul Andrew Crump, Berlin (DE); Michael Peter Grimshaw, Vancouver, WA (US); Prabhuram Thiagarajan, Tucson, AZ (US); Weimin Dong, Vancouver, WA (US); Jun Wang, Camas, WA (US)

Correspondence Address: PATENT LAW OFFICE OF DAVID G. BECK, P. O. BOX 1146, MILL VALLEY, CA, 94942, US

(73) Assignee: nLight Photonics Corporation, Vancouver, WA (US)

(21) Appl. No.: 12/079,475

(22) Filed: Mar. 26, 2008

Related U.S. Application Data
(63) Continuation-in-part of application No. 10/902,224, filed on Jul. 28, 2004, now abandoned.

(51) Int. Cl. H01S 5/00

(52) U.S. Cl. 372/45.012

(57) ABSTRACT

A semiconductor laser and a method of forming the same are provided. The n-side and p-side junctions are independently optimized to improve carrier flow. The material for the n-side cladding layer is selected to yield a small conduction to valance band gap offset ratio while the material for the p-side cladding layer is selected to yield a large conduction to valance band gap offset ratio.

### CROSS-REFERENCE TO RELATED APPLICATION

This application is a continuation-in-part of U.S. patent application Ser. No. 10/902,224, filed Jul. 28, 2004, the disclosure of which is incorporated herein by reference for any and all purposes.

### REFERENCE TO GOVERNMENT CONTRACT

This invention was made with U.S. Government support under Grant No. MDA972-03-C-0101 awarded by DARPA. The United States Government has certain rights in this invention.

### FIELD OF THE INVENTION

The present invention relates generally to semiconductor lasers.

### BACKGROUND OF THE INVENTION

High power diode lasers have been widely used in industrial, graphics, medical and defense applications. Power level, reliability and electrical to optical conversion efficiency are the most important parameters for these lasers with conversion efficiency being of fundamental importance. High electrical to optical conversion efficiency not only saves energy, but is also a means of improving device power level and reliability. The higher the conversion efficiency, the higher the output power that can be achieved for a given input power level. Furthermore, with higher efficiencies there is less heat waste, leading to lower junction temperatures and longer achievable lifetimes.

A diode laser's electrical to optical conversion efficiency is defined as the percentage of output power to input electrical power, the input power being a product of input current and voltage. Therefore lowering a diode laser's operational voltage while maintaining good threshold current and slope efficiency is critical to the electrical to optical conversion efficiency as well as to the output power level and reliability as mentioned above.

A semiconductor material is characterized by band structures, i.e., conduction bands and valence bands. Electron energy is associated with the conduction band while hole energy is associated with the valence band. The energy difference between the two bands is called the energy band gap or the band gap energy. When two layers of different compositions, or band gap energies, are joined together, the band gap energy difference between the layers will be split into a conduction band offset and a valence band offset, with the ratio being determined by the materials systems. For example, the conduction band to valance band offset ratio is about 60/40 for the AlGaAs/GaAs system, while the ratio is about 35/65 for the InGaP/GaAs, AlGaInP/GaAs and InGaAsP/GaAs systems.

A diode laser contains multiple layers which have different band gap energies, doping types and levels. When current is supplied to a diode laser, electrons and holes are injected into the diode from the n-side and p-side contact layers, respectively, the electrons and holes passing through the various layers (e.g., cladding and confinement layers) to the active region, where they combine and generate photons, or light.

Conventional diode laser structures operating in the wavelength range of 700 nm to 1150 nm typically employ AlGaAs-based or InGaAsP-based systems grown on GaAs substrates. In general, in these structures the n-side and p-side cladding layers are selected from the same materials system. As a result, these structures do not equally favor electron and hole transport to the active region. For example, assuming a structure in which AlGaAs is used for both the n- and p-cladding layers, the high conduction band offset with respect to GaAs, near 60% of the total band gap offset, will require excess voltage for electron transport to the active region. In the same structure the valence band offset, near 40% of the total band gap, favors hole transporting. In contrast, electron transporting will be favored if the AlGaAs cladding layers are replaced with AlInGaAsP cladding layers since in this structure a high valance band offset of near 65% will require excess voltage for hole transport to the active region.

Accordingly, what is needed in the art is a diode laser structure that is optimized for both the n-side and p-side junctions, thus leading to lower operational voltages and improved electrical to optical conversion efficiencies. The present invention provides such a structure.

### SUMMARY OF THE INVENTION

The present invention improves diode laser device efficiency by independently optimizing the n-side and p-side junctions, thereby improving carrier flow without requiring the addition of band gap energy transition layers. Specifically, the material for the n-side cladding layer is selected to yield a small conduction to valance band gap offset ratio while the material for the p-side cladding layer is selected to yield a large conduction to valance band gap offset ratio. As a result of these material selections, the transport of electrons and holes to the active region requires lower junction voltages, thus leading to lower operational voltages and higher electrical to optical conversion efficiencies.

In at least one embodiment of the invention, the material selected for the n-side cladding layer yields a conduction to valance band gap offset ratio equal to or smaller than 1:1.5, while the material selected for the p-side cladding layer yields a conduction to valance band gap offset ratio of at least 1.5:1.

In at least one embodiment of the invention, the material selected for the n-side cladding layer yields a conduction to valance band gap offset ratio smaller than 1:2, while the material selected for the p-side cladding layer yields a conduction to valance band gap offset ratio of at least 2:1.

In at least one embodiment of the invention, the material selected for the n-side cladding layer yields a conduction to valance band gap offset ratio smaller than 1:3, while the material selected for the p-side cladding layer yields a conduction to valance band gap offset ratio of at least 3:1.

In at least one embodiment of the invention, the material selected for the n-side cladding layer yields a conduction to valance band gap offset ratio smaller than 1:4, while the material selected for the p-side cladding layer yields a conduction to valance band gap offset ratio of at least 4:1.

A further understanding of the nature and advantages of the present invention may be realized by reference to the remaining portions of the specification and the drawings.

### BRIEF DESCRIPTION OF THE DRAWINGS

FIG. 1 is an illustration of a simple laser diode device structure;

FIG. 2 is a band gap energy diagram for the device illustrated in FIG. 1 for a given set of materials;

FIG. 3 is an illustration of the laser diode device structure shown in FIG. 1 with the addition of six band gap transition layers;

FIG. 4 is a band gap energy diagram for the device illustrated in FIG. 3 for a given set of materials;

FIG. 5 is a band gap energy diagram for a device fabricated in accordance with the invention;

FIG. 6 is a band gap energy diagram for a device fabricated in accordance with the invention in which the band gaps for the two cladding layers are different from one another; and

FIG. 7 is a band gap energy diagram similar to that shown in FIG. 5, with the inclusion of a band gap transition layer between the substrate and the lower cladding layer, and the inclusion of a second band gap transition layer between the upper cladding layer and the contact layer.

### DESCRIPTION OF THE SPECIFIC EMBODIMENTS

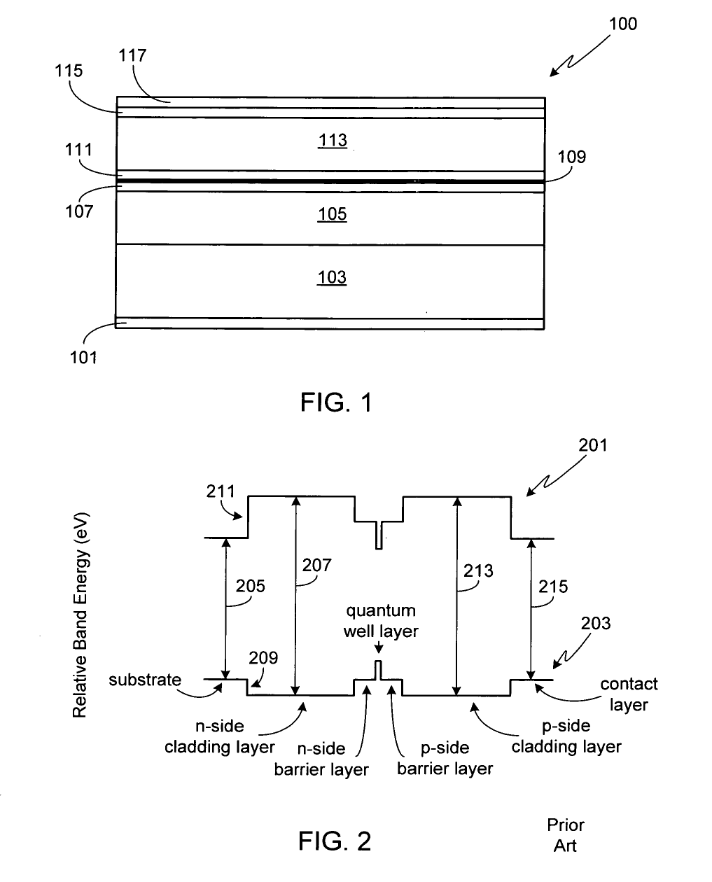

FIG. 1 is a cross-sectional view of an exemplary diode laser structure 100. Assuming that structure 100 is fabricated on an n-type substrate, it is comprised of n-side electrode 101, substrate 103, n-side cladding layer 105, n-side confinement layer 107, quantum well layer 109, p-side confinement layer 111, p-side cladding layer 113, contact layer 115, and p-side electrode 117.

FIG. 2 is a band gap diagram for the central region of structure 100 based on the assumption that a conventional device structure is employed, i.e., one in which both the n-side and p-side cladding layers are comprised of the same material. In FIG. 2, curve 201 represents the conduction band while curve 203 represents the valence band. As shown in the band gap diagram, due to the band gap energies of the substrate (i.e., 205) and the n-side cladding layer (i.e., line 207) the valence band gap offset 209 is much smaller than the conduction band gap offset 211, resulting in a large conduction to valence band gap offset ratio. As this conventional device structure utilizes the same material for the n- and p-side cladding layers, and uses the same material for the substrate and contact layers, the same conduction to valence band gap offset ratio is obtained on the p-side between the p-side cladding (i.e., line 213) and the contact layer (i.e., line 215). Note that in this exemplary structure, a high conduction to valence band gap offset ratio is also seen between the cladding layers and the confinement layers. As a result of the materials selected for the layers in the device schematically illustrated in FIGS. 1 and 2, this structure favors transporting holes into the active region, while requiring excess voltage to transport electrons into the active region.

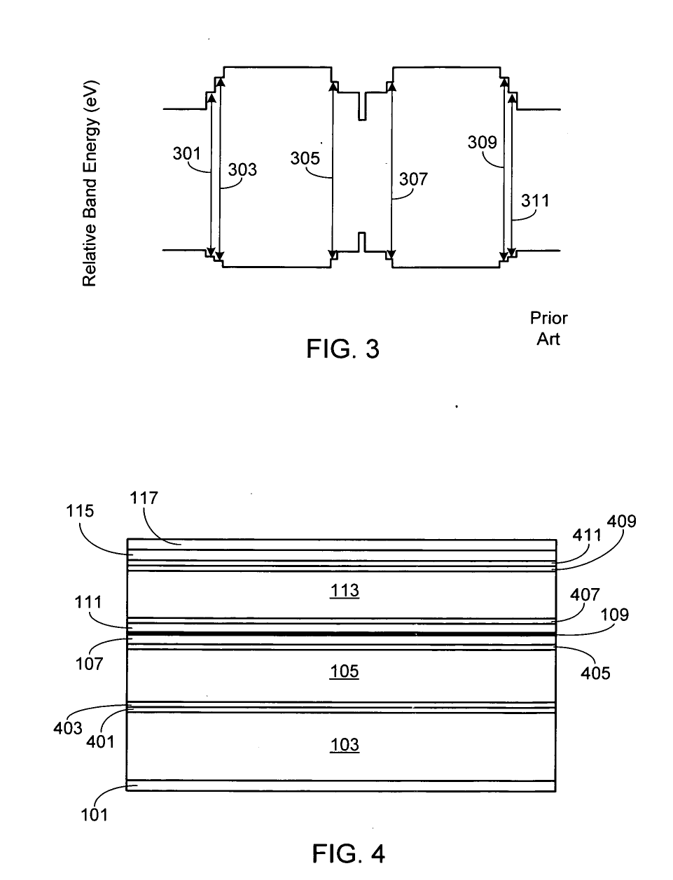

The common approach to overcoming large band gap discontinuities in a structure, thereby aiding carrier flow within the device, is to add one or more layers to the structure. The purpose of these additional layers is to cause a more gradual band gap energy transition between layers, thereby improving carrier flow by requiring a carrier to make a series of small steps rather than a single, larger step in order to overcome the band gap between two layers. An example of such an approach is illustrated by the band gap energy diagram of FIG. 3, which is of the same structure as previously illustrated but with the addition of six new layers. These new layers are represented in the device cross-sectional view of FIG. 4. As shown, two layers 401/403 between substrate 103 and n-side cladding layer 105 have intermediate band gap energies 301/303, respectively; layer 405 between n-side cladding layer 105 and n-side confinement layer 107 has intermediate band gap energy 305; layer 407 between p-side confinement layer 111 and p-side cladding layer 113 has intermediate band gap energy 307; and two layers 409/411 between p-side cladding layer 113 and contact layer 115 have intermediate band gap energies 309/311, respectively. Of course conventional laser diodes may use fewer or greater numbers of band gap energy transition layers than those shown in FIG. 4.

Although the addition of band gap energy transition layers as illustrated in FIGS. 3 and 4 does improve carrier flow, it does so at the cost of device simplicity. In the exemplary embodiment shown in FIG. 4, the device went from requiring seven layers to be grown on the substrate to requiring thirteen layers to be grown, thereby almost doubling the number of layers. In general, as device complexity increases, device fabrication costs also increase. At the same time, the increased device complexity due to the additional layers will typically lower fabrication yield. Accordingly, the prior art approach to improving device efficiency does so at the expense of manufacturing cost and yield.

The present invention improves diode laser device efficiency by independently optimizing the n-side and p-side junctions, thereby improving carrier flow by reducing the band gap energy offsets between layers. Specifically, the material for the n-side cladding layer 105 is selected to yield a small conduction to valance band gap offset ratio while the material for the p-side cladding layer 113 is selected to yield a large conduction to valance band gap offset ratio. Therefore rather than simply adding band gap energy transition layers which replace one large band gap offset with a series of smaller band gap offsets adding up to the same offset as in the prior art approach, the present invention actually reduces the size of the band gap offsets. By reducing the band gap offsets, the barrier height to be overcome by a carrier is reduced, thereby requiring lower junction voltages to transport electrons and holes to the active region. Accordingly, the use of the present invention leads to lower operational voltages and higher electrical to optical conversion efficiencies. Additionally, these benefits can be achieved without increasing device complexity through the addition of more structural layers as in the prior approach.

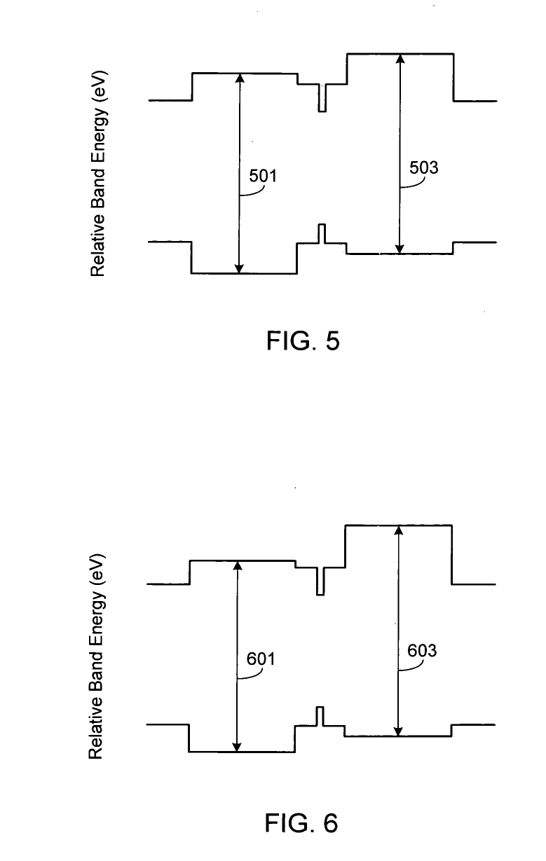

FIGS. 5 and 6 illustrate the band gap energy diagrams for two embodiments of the invention, both utilizing the basic device structure shown in FIG. 1 but with different materials selected for the cladding layers. In the structure illustrated by the band gap energy diagram of FIG. 5, the band gap energy 501 of the n-cladding layer is the same as the band gap energy 503 of the p-cladding layer. However, by selecting materials with the desired electron and hole energies, the band gap energies of these two layers are shifted relative to one another, thereby achieving the desired offset ratios. In the structure illustrated by the band gap energy diagram of FIG. 6, while the desired offset ratios are once again achieved, in this structure the band gap energies of the n-side and p-side cladding layers (601 and 603, respectively) are different.

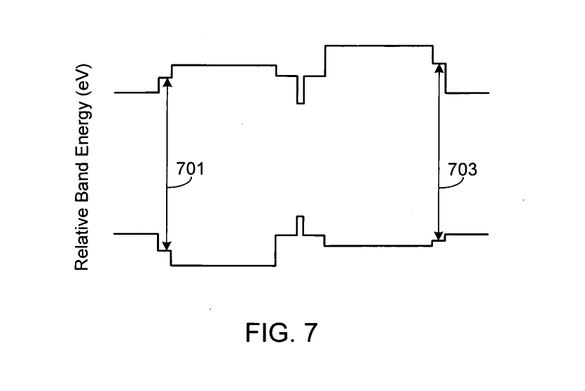

It will be appreciated that due to the limited number of materials available for the design and fabrication of a particular diode laser, in some instances while the desired offset ratios may be achieved, the discontinuity between band gap energies may still be larger than desired. Accordingly in at least one preferred embodiment of the invention, in addition to selecting the n-cladding layer to achieve a small conduction to valance band gap offset ratio and selecting the p-cladding layer to achieve a large conduction to valance band gap offset ratio, transition layers may still be desirable. Thus, for example, in a structure such as that represented by the band gap energy diagram of FIG. 5, a transition layer may be interposed between the substrate and the n-cladding layer and a second transition layer may be interposed between the p-cladding layer and the contact layer. These two layers are represented in FIG. 7 by band gaps 701 and 703, respectively. It should be understood that fewer or greater numbers of band gap energy transition layers can be used, and that they can be interposed between other layers, for example between the cladding and confinement layers. Alternately, and as described above, the transition layers of the prior art can be completely eliminated, thereby allowing a cladding layer to be grown directly onto the substrate, or onto a buffer layer grown on the substrate in order to recondition the substrate surface. Additionally, the confinement layer can be grown directly onto the cladding layer, and the outer cladding layer (e.g., layer 113 in FIG. 1) can be grown directly onto the second confinement layer (e.g., layer 111 in FIG. 1). Additionally, the contact layer can be grown directly onto the outer cladding layer. As used herein, growing one layer on top of another is defined as having no transitional layers interposed between the two.

As previously described, the material for the n-side cladding layer is selected to yield a small conduction to valance band gap offset ratio, thereby aiding electron flow, while the material for the p-side cladding layer is selected to yield a large conduction to valance band gap offset ratio, thereby aiding hole transport. Preferably the ratio of the conduction band gap offset to the valance band gap offset for the n-side cladding layer is equal to or smaller than 1:1.5, more preferably smaller than 1:2, still more preferably smaller than 1:3, and yet still more preferably smaller than 1:4. Preferably the ratio of the conduction band gap offset to the valance band gap offset for the p-side cladding layer is at least 1.5:1, more preferably at least 2:1, still more preferably at least 3:1, and yet still more preferably at least 4:1.

It will be understood that the invention lies in the selection of cladding layer materials that achieve the desired band gap offset ratios noted above, and therefore the invention is not limited to a particular structure or growth technique. For example, the order of the n- and p-type layers of the epitaxial structure can be reversed. Similarly, a device fabricated in accordance with the invention can be grown by a metal organic chemical vapor phase epitaxy (MOCVD), molecular beam epitaxy (MBE), gas source molecular beam epitaxy (GSMBE), chemical beam epitaxy (CBE), metal organic molecular beam epitaxy (MOMBE), liquid phase epitaxy (LPE), etc.

It will also be understood that in addition to the improvements provided by the invention, further improvements are possible through the optimization of the device structure. For example, the composition and thickness of the epitaxial layers can be varied as can the emitter width, front and rear facet reflectivities, cavity length, and assembly techniques, all with the goal of further optimizing the device. Additionally, the active region of a device fabricated in accordance with the invention may comprise either a single or a multi quantum well structure so as to shift the laser emission wavelength and/or reduce the threshold current and slope efficiency, and may be fabricated from any of a variety of materials including, for example, Al, In, Ga, As, P, Sb and N.

It will also be understood by those skilled in the art that a diode laser fabricated in accordance with the invention can employ a simple, single emitter broad area structure or an array comprised of multiple single emitters monolithically integrated on a bar. Alternately, ridge confinement can be used to produce single spatial mode lasers. Alternately, distributed feedback can be used to produce single longitudinal mode laser. Alternately, surface emitting lasers can be produced to achieve higher electrical to optical conversion efficiency.

An exemplary epitaxial structure was fabricated in accordance with the invention, the structure grown on an Si-doped, n+ type GaAs material. An n-type GaAs buffer layer was first grown on the substrate in order to recondition the surface, the buffer layer having a thickness of approximately 0.5 microns. Although not required, in this exemplary structure a transition layer of Si-doped AlGaAs was grown on the buffer layer. The transition layer had a composition that ramped from 5% to 25% and a thickness of 0.04 microns thick. To achieve the desired offset ratio, an approximately 2 micron thick n-side cladding layer comprised of InGaP was grown next. Alternative materials for this layer include InGaAsP and AlGaInP. The n-side cladding layer had a constant doping level of approximately 1×10¹⁸ cm⁻³.

Although the confinement layer could have been grown directly on the n-side cladding layer, a Si-doped AlGaAs transition layer was first grown on the cladding layer, the transition layer having a composition ramping from 25% to 20% and a thickness of 0.05 microns. The transition layer was doped at the same level as the n-side cladding layer. The n-side confinement layer was comprised of AlGaAs with an Al content of 20%. In the exemplary structure, the confinement layer was divided into three sub-layers. The first sub-layer, next to the transition layer, was doped with Si at a concentration of approximately 3×10¹⁷ cm⁻³ and had a thickness of 0.15 microns. The second sub-layer of the confinement layer was undoped and had a thickness of 0.25 microns. The third sub-layer, with a thickness of 0.1 microns, was undoped and had an Al content that ramped down from 20% to 10%.

The active region of the exemplary structure included a quantum well layer bordered on either side by a GaAs barrier layer. The quantum well layer was comprised of InGaAs with an indium content of approximately 14% and a thickness of approximately 70 angstroms, thus achieving a laser wavelength of approximately 940 nanometers.

After the active region, a p-side confinement layer comprised of AlGaAs was grown, the p-side confinement layer preferably comprised of three sub-layers. The first sub-layer, with a thickness of 0.05 microns, was undoped and had an Al content that ramped up from 10% to 30%. The second and third sub-layers had an Al content of 30%. The second sub-layer was undoped and had a thickness of 0.25 microns. The third sub-layer was doped with Zn at a concentration of approximately 3×10¹⁷ cm⁻³ and had a thickness of 0.15 microns.

In the exemplary structure, before growing the p-side cladding layer, a p-type doped transition layer of AlGaAs with an Al composition ramping from 30% to that of the p-side cladding layer was grown. The transition layer, which was 0.05 microns thick, was doped with Zn at a level of approximately 1×10¹⁸ cm⁻³. The growth of p-side cladding layer continued from the growth of the transition layer and had a final thickness of 1 micron. The p-side cladding layer was also fabricated from AlGaAs. In the exemplary structure a thin transition layer of AlGaAs was grown, ramping the Al content down from that of the p-side cladding layer to 5%. Finally a 0.3 micron GaAs contact layer was grown on the structure, the contact layer being doped to a level of 1×10²⁰ cm⁻³.

Broad area lasers were fabricated using the above-described structure and bonded onto copper heat sinks. These diode lasers were tested under CW conditions with the copper heat sink mounted to a cold plate maintained at a temperature of 25° C. during testing. Device output power and voltage were measured with a calibrated integration sphere and a digital multi-meter, respectively. These diode lasers exhibited efficiencies above 60% for currents from 3.1 A to 4.5 A, or output power from 3.0 W to 4.6 W. The peak efficiency of these devices were 60.7% near 3.6 A or 3.7 W. In contrast, laser diodes fabricated using a conventional AlGaAs n-side cladding layer, but otherwise with the same structure, exhibited a peak efficiency of 53% with an operational voltage of about 1.78V at 4 A. The operational voltage of the laser diodes fabricated in accordance with the invention was about 1.67 volts at 4 amps.

As will be understood by those familiar with the art, the present invention may be embodied in other specific forms without departing from the spirit or essential characteristics thereof. Accordingly, the disclosures and descriptions herein are intended to be illustrative, but not limiting, of the scope of the invention which is set forth in the following claims.

What is claimed is:

1. A semiconductor diode laser, comprising:
a substrate;
an n-type buffer layer formed on the substrate;
an n-type cladding layer comprised of a first materials system formed on the n-type buffer layer, said first materials system having a first conduction band to valence band offset ratio;
a first confinement region formed on the n-type first cladding layer;
an active region formed on the first confinement layer;
a second confinement region formed on the active layer;
a p-type cladding layer comprised of a second materials system formed on the second confining layer, said second materials system having a second conduction band to valence band offset ratio, wherein said second conduction band to valence band offset ratio is larger than said first conduction band to valence band offset ratio; and
a p-type contact layer formed on the p-type cladding layer.

2. The semiconductor diode laser of claim 1, wherein said first conduction band to valence band offset ratio is equal to or smaller than 1:1.5, and wherein said second conduction band to valence band offset ratio is at least 1.5:1.

3. The semiconductor diode laser of claim 1, wherein said first conduction band to valence band offset ratio is smaller than 1:2, and wherein said second conduction band to valence band offset ratio is at least 2:1.

4. The semiconductor diode laser of claim 1, wherein said first conduction band to valence band offset ratio is smaller than 1:3, and wherein said second conduction band to valence band offset ratio is at least 3:1.

5. The semiconductor diode laser of claim 1, wherein said first conduction band to valence band offset ratio is smaller than 1:4, and wherein said second conduction band to valence band offset ratio is at least 4:1.

6. The semiconductor diode laser of claim 1, wherein said n-type cladding layer is formed directly on said n-type buffer layer, and wherein said p-type contact layer is formed directly on said p-type cladding layer.

7. The semiconductor diode laser of claim 6, wherein said first confinement region is formed directly on said n-type first cladding layer, and wherein said p-type cladding layer is formed directly on said second confinement region.

8. The semiconductor diode laser of claim 1, wherein said active region contains a quantum well.

9. The semiconductor diode laser of claim 1, wherein said active region contains a multi-quantum well structure.

10. A semiconductor diode laser, comprising:
a substrate;
a p-type buffer layer formed on the substrate;
a p-type cladding layer comprised of a first materials system formed on the p-type buffer layer, said first materials system having a first conduction band to valence band offset ratio;
a first confinement region formed on the p-type first cladding layer;
an active region formed on the first confinement layer;
a second confinement region formed on the active layer;
an n-type cladding layer comprised of a second materials system formed on the second confining layer, said second materials system having a second conduction band to valence band offset ratio, wherein said first conduction band to valence band offset ratio is smaller than said second conduction band to valence band offset ratio; and
an n-type contact layer formed on the n-type cladding layer.

11. The semiconductor diode laser of claim 10, wherein said first conduction band to valence band offset ratio is at least 1.5:1, and wherein said second conduction band to valence band offset ratio is equal to or smaller than 1:1.5.

12. The semiconductor diode laser of claim 10, wherein said first conduction band to valence band offset ratio is at least 2:1, and wherein said second conduction band to valence band offset ratio is smaller than 1:2.

13. The semiconductor diode laser of claim 10, wherein said first conduction band to valence band offset ratio is at least 3:1, and wherein said second conduction band to valence band offset ratio is smaller than 1:3.

14. The semiconductor diode laser of claim 10, wherein said first conduction band to valence band offset ratio is at least 4:1, and wherein said second conduction band to valence band offset ratio is smaller than 1:4.

15. The semiconductor diode laser of claim 10, wherein said p-type cladding layer is formed directly on said p-type buffer layer, and wherein said n-type contact layer is formed directly on said n-type cladding layer.

16. The semiconductor diode laser of claim 15, wherein said first confinement region is formed directly on said p-type first cladding layer, and wherein said n-type cladding layer is formed directly on said second confinement region.

17. The semiconductor diode laser of claim 10, wherein said active region contains a quantum well.

18. The semiconductor diode laser of claim 10, wherein said active region contains a multi-quantum well structure.

19. A method of configuring a semiconductor diode laser, said method comprising the steps of selecting a first material for an n-side cladding layer that yields a first conduction band to valence band offset ratio, and selecting a second material for a p-side cladding layer that yields a second conduction band to valence band offset ratio, wherein said second conduction band to valence band offset ratio is larger than said first conduction band to valence band offset ratio.

20. The method of claim 19, further comprising the step of selecting said first material to yield said first conduction band to valence band offset ratio of 1:1.5 or less, and further comprising the step of selecting said second material to yield said second conduction band to valence band offset ratio of at least 1.5:1.
